(19) United States
(12) Patent Application Publication
(10) Pub. No.: US 2009/0302298 A1
(43) Pub. Date: Dec. 10, 2009

(54) Forming sublithographic phase change memory heaters

(76) Inventors: Jong-Won S. Lee, San Francisco, CA (US); Gianpaolo Spadini, Campbell, CA (US)

Correspondence Address: TROP, PRUNER & HU, P.C., 1616 S. VOSS RD., SUITE 750, HOUSTON, TX, 77057-2631, US

(21) Appl. No.: 12/156,851

(22) Filed: Jun. 5, 2008

(51) Int. Cl. H01L 45/00; H01L 21/311

(52) U.S. Cl. 257/4; 438/702; 257/E21.249; 257/E45.002

(57) ABSTRACT

A phase change memory may be formed with a sublithographic heater by using a mask with a sidewall spacer to etch an opening in a dielectric layer. The opening then has a sublithographic lateral extent. The resulting via may be filled with a heater material to form a sublithographic heater.

### BACKGROUND

This relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged schematic cross-sectional view of one embodiment of the present invention at an early stage of manufacture;

FIG. 2 is a view corresponding to FIG. 1 at a subsequent stage;

FIG. 3 is a view corresponding to FIG. 2 at a subsequent stage;

FIG. 4 is a view corresponding to FIG. 3 at a subsequent stage;

FIG. 5 is a view corresponding to FIG. 4 at a subsequent stage;

FIG. 6 is a view corresponding to FIG. 5 at a subsequent stage;

FIG. 7 is a view corresponding to FIG. 6 at a subsequent stage; and

FIG. 8 is a schematic depiction of a system in accordance with one embodiment.

### DETAILED DESCRIPTION

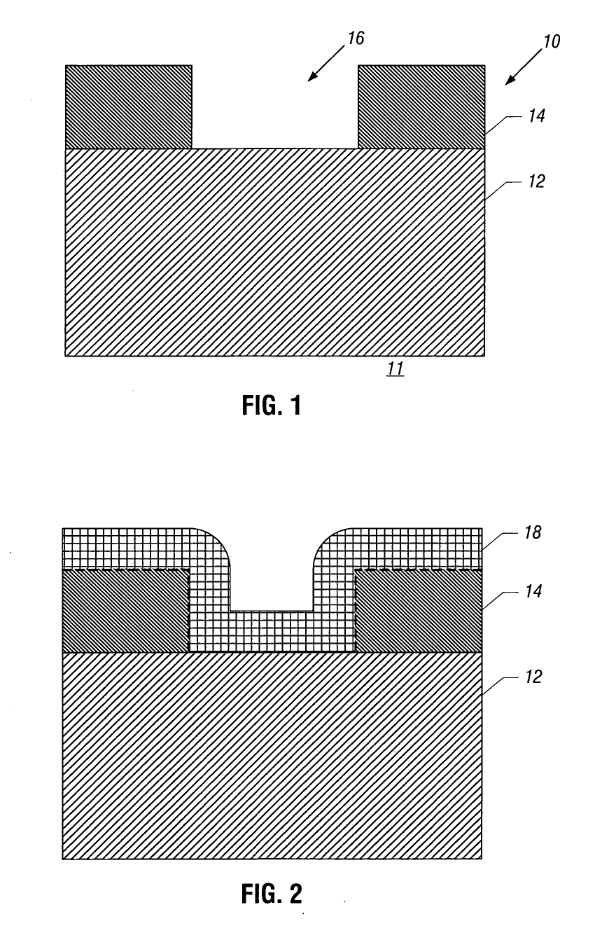

Referring to FIG. 1, a layer 12 may be formed of suitable dielectric materials over a bottom interconnect metal in one embodiment. In one embodiment, the layer 12 may be silicon oxide, having a thickness of about 1400 Angstroms. The lower interconnect 11 supplies electrical current to the device.

Over the dielectric layer 12 may be a masking layer 14 which has been patterned with an opening 16. In one embodiment, the layer 14 is silicon nitride. Photolithographic techniques (e.g., photoresist patterning and silicon nitride etch) may be used to form the opening 16. Thus, the minimum feature size of the lateral dimension of the opening 16 is subject to the limitations of photolithography.

Referring to FIG. 2, a sidewall spacer material 18 may be deposited over the masking layer 14 in accordance with one embodiment. The spacer material 18 may be formed of any suitable material, including polysilicon or dielectric materials such as oxide or nitride.

In one embodiment, the height of the masking layer 14 is very small and, therefore, the aspect ratio of the spacer material 18 may be very low. For example, in some embodiments, the height of the masking layer 14 may be less than 500 Angstroms.

As a result, low temperature techniques may be utilized to deposit the spacer material 18, including plasma enhanced chemical vapor deposition (PECVD) which uses temperatures below 400° C. The use of low temperatures may be advantageous compared to techniques which involve greater temperatures such as chemical vapor deposition. The use of PECVD may also be advantageous compared to techniques, such as atomic layer deposition, in terms of cost and throughput.

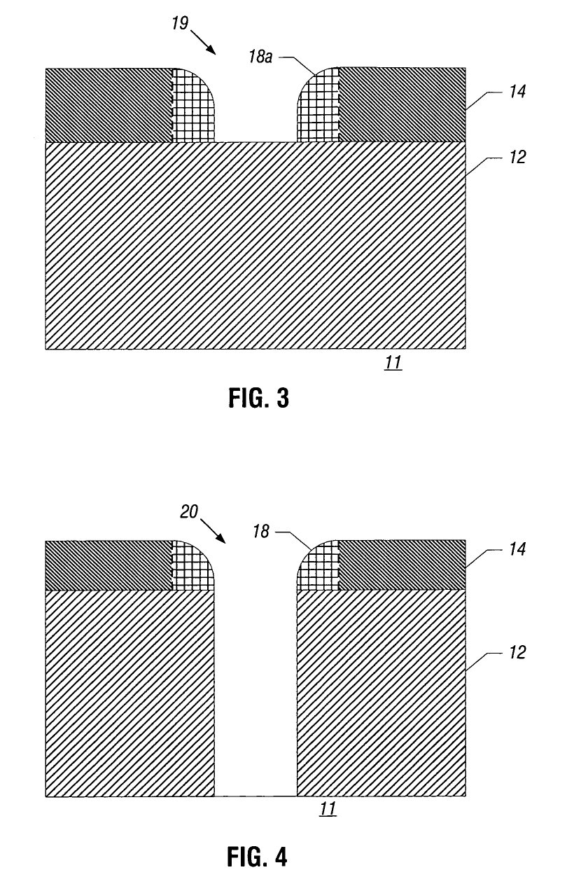

Referring to FIG. 3, an anisotropic etch may be used to form sidewall spacers 18a. The resulting lateral dimension of the remaining opening 19 is now sublithographic in that it is less than the dimensions possible with photolithography. In one embodiment, the anisotropic etch may be done by dry etching to open up the spacer material 18 at the bottom of the contact.

Using the layer 14 and the spacers 18a as a mask, a chemically selective plasma etching may be done to form a sublithographic via 20, as shown in FIG. 4. In an embodiment, where the spacers 18a are silicon nitride, and the dielectric 12 is silicon oxide, the etching may be done using plasma etch processing using a mixture of C4F6/CF4/O2. The via 20 extends all the way down to the bottom interconnect 11 and may stop on an underlying contact (not shown) within the underlying substrate 11.

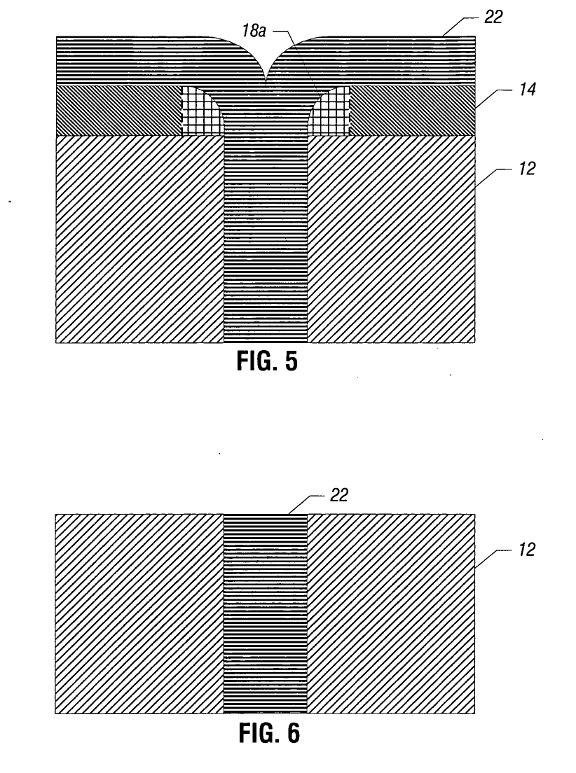

Then, referring to FIG. 5, a heater material 22 may be deposited in the via 20. A suitable material for the heater 22 include titanium silicon nitride.

After chemical mechanical planarization, the overlying portion of heater material 22, the sidewall spacers 18a, and the layer 14 are removed, as shown in FIG. 6. A heater 22, shown in FIG. 6, is formed in the sublithographic via 20 and, as a result, the heater 22, itself, also has a sublithographic lateral dimension.

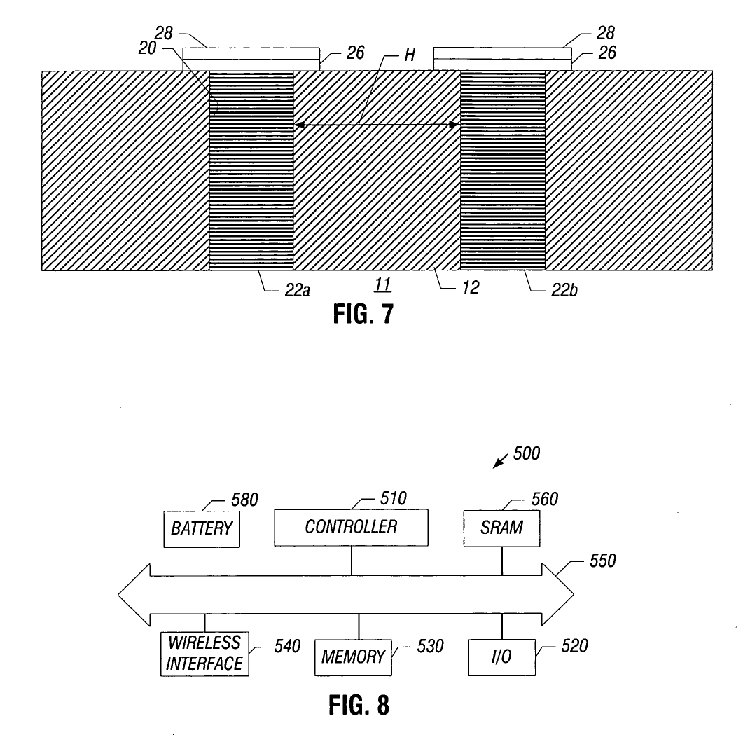

Thereafter, as shown in FIG. 7, a chalcogenide layer 26 may be deposited. Then, an upper contact electrode 28 may be deposited. While a planar layer 26 and planar electrode 28 are shown, these layers may be patterned and etched to smaller lateral dimensions in some embodiments.

In FIG. 7, two adjacent pores 20, each filled with a heater 22 and, particularly, a heater 22a or 22b are depicted. Between the two adjacent pores 20 is a dielectric material 12.

Programming to alter the state or phase of the material may be accomplished by applying voltage potentials to the upper electrode 28 and a lower electrode (not shown) in substrate 11, thereby generating a voltage potential across a memory element including a phase change layer 26. When the voltage potential is greater than the threshold voltages of any select device and memory element, then an electrical current may flow through the phase change layer 26 in response to the applied voltage potentials, and may result in heating of the phase change layer 26.

This heating may alter the memory state or phase of the layer 26, in one embodiment. Altering the phase or state of the material 10 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 8, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a mask with an opening over a dielectric layer;
forming a sidewall spacer in said opening;
etching said dielectric layer under said opening using said mask and said sidewall spacer to form a via in said dielectric layer; and
depositing a heater material in said via.

2. The method of claim 1 including forming said spacer by depositing a spacer material using temperatures below 400° C.

3. The method of claim 2 including depositing said spacer material using chemical vapor deposition.

4. The method of claim 3 including depositing said spacer material using plasma enhanced chemical vapor deposition.

5. The method of claim 1 including forming the mask of photoresist.

6. The method of claim 1 including forming said mask with a height of less than 500 Angstroms.

7. A phase change memory comprising:
a pair of spaced, sublithographic pores;
an homogeneous dielectric material extending between said pores;
a heater in each pore; and
a phase change material over said heater.

8. The memory of claim 7 wherein said phase change material is planar.

9. The memory of claim 8 including an electrode over said phase change material, said electrode being planar and parallel to said phase change material.

10. The memory of claim 9 including a separate planar phase change material and a separate planar electrode over each of said heaters.

11. A semiconductor structure comprising:
a dielectric layer;
a second layer over said dielectric layer, said second layer having an opening;
a sidewall spacer in said opening;
a pore extending through said sidewall spacer and said dielectric layer; and
a heater material in said pore.

12. The structure of claim 11 wherein said pore is sublithographic.

13. The structure of claim 11 wherein said second layer has a height of less than 500 Angstroms.

14. The structure of claim 13 wherein said second layer is photoresist.

15. A method comprising:
forming a mask having a vertical height with less than 500 Angstroms over a dielectric layer;
forming a sidewall spacer is said mask;
using said mask and said spacer to etch an opening in said dielectric layer; and
depositing a heater in said opening.

16. The method of claim 15 including forming said spacer by depositing a spacer material using temperatures below 400° C.

17. The method of claim 16 including depositing said spacer material using chemical vapor deposition.

18. The method of claim 17 including depositing said spacer material using plasma enhanced chemical vapor deposition.

19. The method of claim 15 including forming the mask of photoresist.

20. A system comprising:
a processor;
a battery coupled to said processor; and
a phase change memory including a pair of spaced, sublithographic pores, and homogenous dielectric material extending between said pores, a heater in each pore, and a phase change material over said heater.

21. The system of claim 20 wherein said phase change material is planar.

22. The system of claim 21 including an electrode over said phase change material, said electrode being planar and parallel to said phase change material.

23. The system of claim 22 including a separate planar phase change material and a separate planar electrode over each of said heaters.
